(19) United States
(12) Patent Application Publication
(10) Pub. No.: US 2009/0008132 A1
(43) Pub. Date: Jan. 8, 2009

(54) FLEXIBLE WIRING BOARD FOR TAPE CARRIER PACKAGE

(75) Inventors: Ryoichi Takasawa, Ube-shi (JP); Yukinori Kohama, Ube-shi (JP); Masahiro Naiki, Ube-shi (JP)

Correspondence Address: KNOBBE MARTENS OLSON & BEAR LLP, 2040 MAIN STREET, FOURTEENTH FLOOR, IRVINE, CA, 92614, US

(73) Assignee: UBE INDUSTRIES, LTD., Yamaguchi (JP)

(21) Appl. No.: 12/167,835

(22) Filed: Jul. 3, 2008

(30) Foreign Application Priority Data
Jul. 6, 2007 (JP) 2007-178752

(51) Int. Cl. H05K 1/00; C08L 83/04; C08L 77/06; C08L 79/08; C08L 75/04

(52) U.S. Cl. 174/254; 524/588; 524/606; 524/612

(57) ABSTRACT

A flexible wiring board for a tape carrier package with reduced tackiness and a tape carrier package formed by using the flexible wiring board is disclosed. The flexible wiring board for a tape carrier package has an insulating film 1, a wiring pattern 3 formed on a surface of the insulating film, and an overcoat layer 9 containing a resin cured material and a porous fine particle, and protecting at least a region of said wiring pattern.

### CROSS REFERENCE TO RELATED APPLICATION

This application claims the benefit and priority to Japanese Application Number 2007-178752, filed on Jul. 6, 2007, which is hereby incorporated by reference in its entirety.

### BACKGROUND OF THE INVENTION

1. Technical Field

The present invention relates to a flexible wiring board for a tape carrier package, and to a tape carrier package. In particular, the invention relates to a flexible wiring board for a tape carrier package with reduced tackiness wherein an overcoat layer is composed of a curable resin composition containing porous fine particle, particularly porous silica, as a filler, and a tape carrier package formed by using the flexible wiring board.

2. Background Art

A tape carrier package is a package obtained by mounting electronic parts such as a semiconductor chip or the like by, for example, TAB (tape automated bonding) or COF (chip on film) technique on a flexible wiring board for a tape carrier package. This flexible wiring board for a tape carrier package is provided with wiring patterns formed on the surface of an insulating film and the surface of the wiring patterns excluding connecting portions such as inner leads, outer leads or the like is protected by an electro-insulating overcoat layer.

The overcoat layer is suitably formed by using a polyurethane resin composition, a polyamideimide resin composition, a polyimide-based resin composition or the like. In Patent Documents 1 and 2, there has been disclosed a polyurethane resin composition as a composition for overcoat; in Patent Document 3, a polyamideimide resin composition as a composition for overcoat; in Patent Document 4, a polyimidesiloxane resin composition as a composition for overcoat; and in Patent Document 5, a modified polyimide resin composition as a composition for overcoat.

Electronic parts such as a semiconductor chip and the like are usually continuously mounted on the flexible wiring board for a tape carrier package. In its process, the flexible wiring board for a tape carrier package is continuously taken out from a reel with the winding of the board around the reel if necessary and accordingly used.

The overcoat layer in the flexible wiring board for a tape carrier package is formed by curing a coating film of a thermosetting or photosetting resin composition. In many cases, since tackiness on the surface of the overcoat layer is bad (high tackiness), when a flexible wiring board for a tape carrier package is directly wound around a reel, there is a problem in that the overlap regions stick together. For that reason, the film is generally wound around a reel via a peeling film such as a PET film or the like.
Patent Document 1: Japanese Patent Laid-open No. 1999-61037
Patent Document 2: Japanese Patent Laid-open No. 2007-39673
Patent Document 3: Japanese Patent Laid-open No. 1999-12500
Patent Document 4: Japanese Patent Laid-open No. 2004-211064
Patent Document 5: Japanese Patent Laid-open No. 2006-307183
Patent Document 6: Japanese Patent Laid-open No. 2002-151809
Patent Document 7: Japanese Patent Laid-open No. 2006-63297
Patent Document 8: Japanese Patent Laid-open No. 2007-138095

### SUMMARY OF THE INVENTION

In late year, in the winding of flexible wiring boards for a tape carrier package, for the purpose of low cost, reel winding which does not employ a peeling film such as a PET film or the like has been in demand. Furthermore, in a process for forming an overcoat layer of a flexible wiring board for a tape carrier package, when a resin composition is cured after continuously coated by screen printing or the like, an easier way of curing has been studied for enhancing the productivity (for example, at lower temperatures curing or short time curing in case of thermosetting resins). In that case, there is a problem in that tackiness of the obtained flexible wiring board for a tape carrier package is increased in many cases (adhesiveness becomes high). On the other hand, high tackiness of the flexible wiring board for a tape carrier package deteriorates conveyance property in a mounting process for mounting a semiconductor chip using the flexible wiring package. Therefore, a flexible wiring board for a tape carrier package with reduced tackiness has been strongly demanded.

An object of the present invention is to provide a flexible wiring board for a tape carrier package with reduced tackiness and a tape carrier package formed by using the flexible wiring board.

The present invention and preferred embodiments are specified by items as described below.

1. A flexible wiring board for a tape carrier package comprising:
an insulating film,
a wiring pattern formed on a surface of the insulating film, and
an overcoat layer containing a resin cured material and a porous fine particle, and protecting at least a region of the wiring pattern.

2. The flexible wiring board for a tape carrier package according to item 1, wherein tackiness of the overcoat layer satisfies the conditions such that the overcoat layer is not attached to SUS at 140 degree centigrade and is not attached to polyimide at 60 degree centigrade.

3. The flexible wiring board for a tape carrier package according to item 1 or 2, wherein the porous fine particle is contained in the ratio of 0.1 to 50 weight parts, based on 100 weight parts of the resin cured material.

4. The flexible wiring board for a tape carrier package according to any one of items 1 to 3, wherein an average particle diameter of the porous fine particle is smaller than the thickness of the overcoat layer, and

porous fine particles are present more in population on the surface than in the central portion in the thickness direction of the overcoat layer.

5. The flexible wiring board for a tape carrier package according to any one of items 1 to 4, wherein an average particle diameter of the porous fine particle is not more than 30 μm and a specific surface area thereof is not less than 200 m²/g.

6. The flexible wiring board for a tape carrier package according to any one of items 1 to 5, wherein a pore volume of the porous fine particle is not less than 0.1 ml/g converted at the oil absorption of the refined linseed oil method according to JIS K 5101-13-1.

7. The flexible wiring board for a tape carrier package according to any one of items 1 to 6, wherein the porous fine particle is porous silica.

8. The flexible wiring board for a tape carrier package according to any one of items 1 to 7, wherein the resin cured material contains a cured material of at least one resin selected from the group consisting of a polyurethane resin, a polyamideimide resin, a polyimidesiloxane resin and a modified polyimide resin.

9. The flexible wiring board for a tape carrier package according to any one of items 1 to 8, wherein the resin cured material is heated by far infrared rays and cured.

10. The flexible wiring board for a tape carrier package according to any one of items 1 to 9, wherein it is wound round a reel without through a peeling film.

11. A tape carrier package formed by using the flexible wiring board for a tape carrier package according to any one of items 1 to 10.

12. A curable resin composition for overcoat, wherein a porous fine particle and a curable resin are contained, and when cured, tackiness on the surface of the resin cured material is reduced as compared to a case in which no porous fine particle is present.

13. The curable resin composition for overcoat according to item 12, wherein the tackiness satisfy the conditions such that the resin cured material is not attached to SUS at 140 degree centigrade and is not attached to polyimide at 60 degree centigrade after curing.

14. The curable resin composition for overcoat according to item 12 or 13, wherein the curable resin contains at least one resin selected from the group consisting of a polyurethane resin, a polyamideimide resin, a polyimidesiloxane resin and a modified polyimide resin.

According to the present invention, it is possible to provide a flexible wiring board for a tape carrier package with reduced tackiness and a tape carrier package formed by using the flexible wiring board. As a result, it is possible to eliminate a peeling film when a flexible wiring board for a tape carrier package is wound around a reel, improve the productivity in a process for the manufacture of the flexible wiring board for a tape carrier package, enhance conveyance property in a mounting process using the flexible wiring board for a tape carrier package, and the like.

### BRIEF DESCRIPTION OF THE DRAWINGS

FIG. 1 is a schematic plan view partially showing a representative example of the tape carrier package of the present invention.

FIG. 2 is a partial sectional view taken at the A-A′ line of FIG. 1.

FIG. 3 is a schematic plan view partially showing a representative example of the tape carrier package of the present invention.

FIG. 4 is a partial sectional view taken at the B-B′ line of FIG. 3.

### REFERENCE NUMBERS IN THE DRAWINGS

1 insulating film
2 adhesive layer
3 wiring pattern
3a inner leads (wiring pattern)
3b outer leads (wiring pattern)
3c test pad (wiring pattern)
4 device hole
5 bending slits
6 bump
7 semiconductor chip
8 flex resin layer
9 overcoat layer (solder resist layer)
10 semiconductor-encapsulating resin
11 perforation holes (sprocket holes)
12 insulating film
13 wiring pattern
13a inner leads (wiring pattern)
13b outer leads (wiring pattern)
13c test pad (wiring pattern)
14 bump
15 semiconductor chip
16 overcoat layer (solder resist layer)
17 underfill material
18 perforation holes (sprocket holes)

### DETAILED DESCRIPTION OF THE INVENTION

As described above, in the present invention, porous fine particles contained in a resin cured material reduce tackiness on the surface of an overcoat layer. In the past, a resin composition for forming the overcoat layer contains inorganic particles such as non-porous silica or the like for the improvement of thixotropic property (Patent Documents 1, 3 and others). However, these inorganic particles had no effect on the improvement of tackiness.

Furthermore, in Japanese Patent Laid-open No. 2002-151809 (Patent Document 6), there has been disclosed an electronic material for a printed wiring board containing in a coating component silica gel on which an insect repellent such as a pyrethroid-based drug is supported. However, the invention relates to insect repellency for a rigid printed wiring board such as a paper-phenol insulating layer (a substrate), and does not relate to improvement of tackiness of a flexible wiring board for a tape carrier package. Furthermore, in Japanese Patent Laid-open No. 2006-63297 (Patent Document 7), there has been described formation of an insulating resin film from a resin composition containing porous substance filled with a low dielectric agent, but the invention does not relate to an overcoat layer nor improvement of tackiness. Meanwhile, in Japanese Patent Laid-open No. 2007-138095 (Patent Document 8), there has been described a curable resin composition with improved high frequency response in which hydrophobic inorganic porous media is contained for preventing moisture absorption and water absorption of the inorganic porous media and suppressing the increase of the dielectric constant, whereas it does not relate to improvement of tackiness of the flexible wiring board for a tape carrier package.

It has not yet been known that tackiness of the overcoat layer is reduced due to porous fine particles.

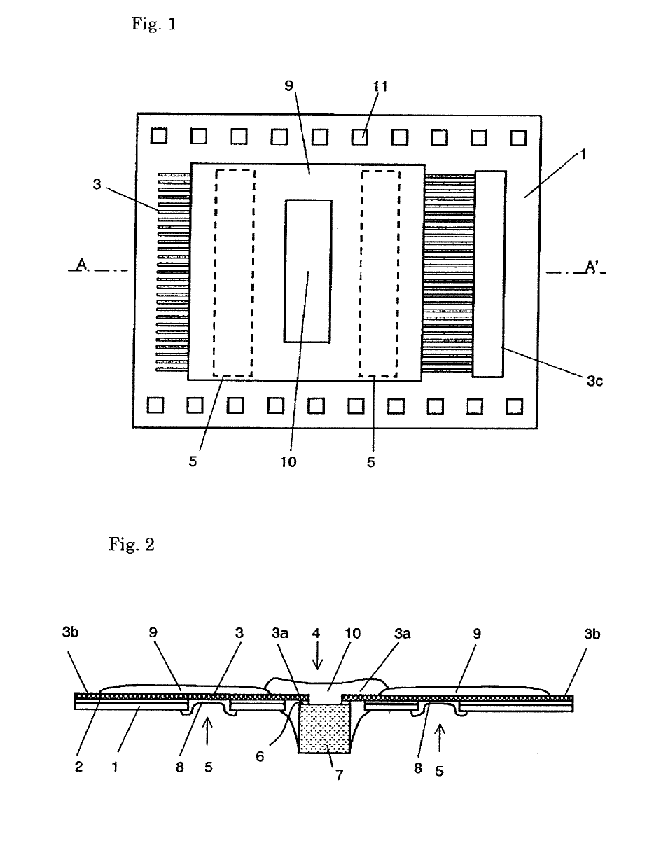

Firstly, the structure of the flexible wiring board of the present invention will be described with reference to the drawings. FIG. 1 is a schematic plan view partially showing a representative example of the tape carrier package of the present invention, and FIG. 2 is a partial sectional view taken at the A-A′ line of FIG. 1. A wiring pattern 3 is attached on the surface of an insulating film 1 via an adhesive layer 2. The wiring pattern 3 has inner leads 3a at a device hole 4, crosses bending slits 5, and has outer leads 3b for connection with other parts at the end portion. The inner leads 3a are connected with a semiconductor chip 7 via bumps 6. A flex resin layer 8 is formed on one side of a portion of the wiring pattern 3 where it crosses the bending slits 5, for protection of the wiring pattern. Further, an overcoat layer 9 (a solder resist layer) is formed on the main surface of the region where the wiring pattern 3 is formed for protection of the wiring pattern, excluding the region where the inner leads 3a and the outer leads 3b are formed. The semiconductor chip 7 connected with the inner leads 3a is encapsulated and protected by a semiconductor-encapsulating resin 10. At the end portion of the package, perforation holes 11 (sprocket holes) and a test pad 3c (a wiring pattern) are formed.

The tape carrier package of the present invention is not restricted to the embodiment shown in FIGS. 1 and 2. In the embodiment of FIGS. 1 and 2, the bending slits are formed at two sites, but may be formed at one site or at a plurality of sites. In the embodiment of FIGS. 1 and 2, only one side (a back side) of the wiring pattern crossing the bending slits is covered with a flex resin layer, but the both sides may also be covered with the flex resin layer.

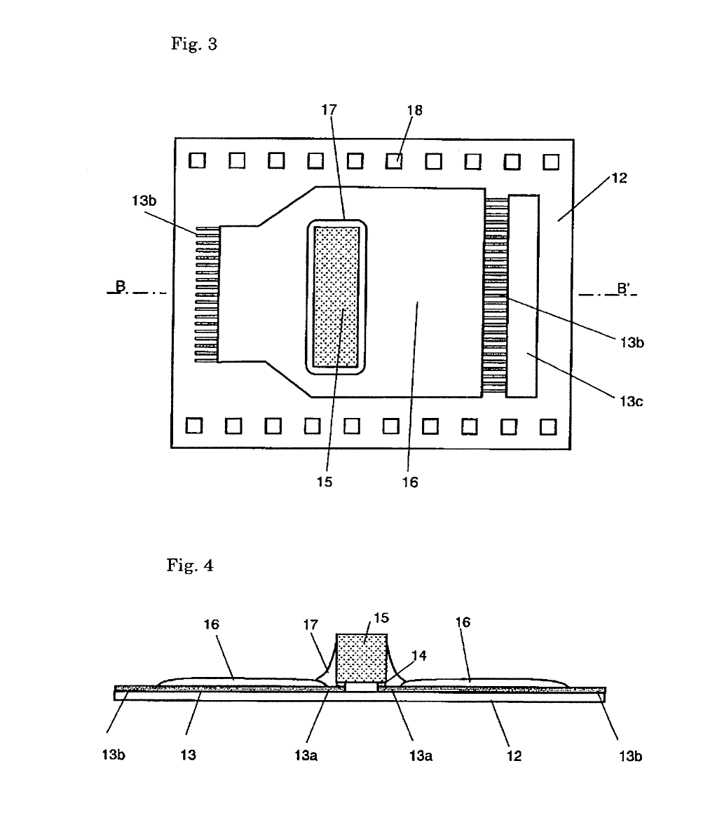

FIG. 3 is a schematic plan view showing a representative structure of the tape carrier package according to the COF technology, and FIG. 4 is a schematic sectional view taken at the B-B′ line of FIG. 3. A wiring pattern 13 is attached on the surface of an insulating film 12. The wiring pattern 13 has inner leads 13a for connection with a semiconductor chip, and has outer leads 13b for connection with other parts. The inner leads 13a are connected with a semiconductor chip 15 via bumps 14. An overcoat layer 16 (a solder resist layer) is formed on the main surface of the region where the wiring pattern 13 is formed for protection of the wiring pattern, excluding the region where the inner leads 13a and the outer leads 13b are formed. Furthermore, the semiconductor chip 15 connected with the inner leads 13a is encapsulated and protected by an underfill material 17. At the end portion of the package, perforation holes 18 (sprocket holes) and a test pad 13c (a wiring pattern) are formed.

In the present invention, the flexible wiring board for a tape carrier package means a wiring board having flexibility, (i) in which the electronic parts such as a semiconductor chip or the like, the encapsulating resin for protection thereof, etc are excluded from the structure of a tape carrier package (i.e. the structure before these electronic parts are formed), and (ii) in which the wiring pattern is formed on the surface of the insulating film, and at least a region where the wiring pattern is formed excluding the connection portion of the aforementioned wiring pattern such as inner leads and outer leads is protected by an electro-insulating overcoat layer. That is, the flexible wiring board refers to both a wiring board which is present in the tape carrier package, and a wiring board which is provided for use in a tape carrier package. The flexible wiring board for a tape carrier package may optionally comprise an adhesive layer, a flex resin layer or the like.

Ordinarily, the flexible wiring board for a tape carrier package is formed on a long insulating film having, at the both end protions, pairs of perforation holes (sprocket holes). In the mounting process, the flexible wiring board for a tape carrier package is often continuously taken out from a roll wound around a reel and is subjected to step of mounting electronic parts such as a semiconductor chip or the like, encapsulating using an encapsulating resin, and if necessary treating with solder and the like; whereby a tape carrier package is formed. In a mounting process, a reel-to-reel method may be employed wherein, in addition to a flexible wiring board for a tape carrier package to be supplied, a tape carrier package formed via a mounting process is wound around a reel.

The insulating film used in the present invention is a heat-resistant insulating film, and is preferably a film made of a heat-resistant polymer which has a high resistance to dielectric breakdown, a low dielectric loss tangent, high heat resistance, flexibility, appropriate rigidity, chemical resistance, a low thermal shrinkage ratio and a superior dimensional stability to moisture absorption. The insulating film is preferably an aromatic polyimide film, an aromatic polyamideimide film, or an aromatic polyester film, and particularly preferably an aromatic polyimide film. Specific examples include UPILEX produced by Ube Industries, Ltd. and KAPTON produced by Du Pont. Furthermore, the thickness of the insulating film is preferably from 2 to 150 μm, and ordinarily from 5 to 125 μm.

The wiring pattern is formed from an electro-conductive metal foil. As the metal foil, a copper foil, an aluminum foil, etc., are suitably used. The copper foil may be a rolled copper foil or an electrolytic copper foil. The thickness of the wiring pattern is suitably from 2 to 100 μm. Furthermore, the line width of the wiring pattern is suitably from about 5 to about 500 μm, and particularly about 20 to about 300 μm. The line space of the wiring pattern is suitably from about 5 to about 500 μm, and particularly from about 20 to about 400 μm.

The insulating film and the wiring pattern may be directly laminated in some cases, or laminated via an adhesive layer sin some cases. For the adhesive layer, there can be preferably used an epoxy type adhesive or a phenol type adhesive, which is superior in adhesiveness, insulation reliability, heat resistance and chemical resistance, is small in warpage after curing, and has high flatness. A modified epoxy resin adhesive superior in flexibility is particularly suitable. Specific examples include adhesive films #7100, #8200, #8600 and the like produced by Toray Industries, Inc. The thickness of the adhesive layer is suitably from about 1 to 30 μm, and particularly from about 2 to 20 μm.

Furthermore, in the wiring board for a tape carrier package for TAB application, bending slits are formed on the insulating film. Since the wiring pattern crosses the bending slit portion, the flex resin layer is formed for protection of the wiring pattern. The flex resin layer is preferably formed by using a curable resin composition which can be easily coated on the bending slit portion by a method such as printing or the like and has good adhesiveness to a substrate, and which has excellent properties after having been cured, such as good insulation reliability, adhesiveness, heat resistance and chemical resistance, reduced warpage, superior flatness and such flexibility that, even when the bending slit portion is bent, causes neither peeling nor breakage and can be used sufficiently. Specifically, for examples, a cured material of a polyurethane resin composition, a polycarbonate resin composition, a polyamideimide resin composition or a polyimidesiloxane resin composition is suitably used. Of these materials, a cured material of a polyimidesiloxane resin composition is particularly suitably used. As a preferable specific example, there can be mentioned UPICOAT FS-100L produced by Ube Industries, Ltd. made from a polyimidesiloxane resin composition. The thickness of the flex resin layer is preferably from about 0.2 to 5 times of the thickness of the wiring pattern crossing the bending slits and is suitably from about 0.5 to 200 μm, particularly preferably from about 1 to 100 μm, and further preferably from about 5 to 50 μm.

The overcoat layer (a solder resist layer) is a protective film which covers the surface of the wiring pattern region including the surface of the wiring pattern and the space between wiring patterns. The overcoat layer is formed suitably by using a curable resin composition which is coated by a method such as printing or the like and then dried and cured by heating, an irradiation with a light or the like. The overcoat layer is required to have various properties such as small warpage property, superior flatness, good adhesiveness to the insulating film and wiring pattern, excellent electro-insulation reliability, heat resistance, metal plating resistance, resistance to penetration of tin into boundary, chemical resistance, solvent resistance (e.g. acetone resistance), bending resistance (without causing peeling or whitening at the time of bending), adhesiveness to an encapsulating resin (also including underfill) or the like.

When the overcoat layer is in a state of covering and protecting the wiring pattern, the overcoat layer refers to both an overcoat layer which is present in a flexible wiring board for a tape carrier package in a state that electronic parts such as a semiconductor chip or the like are not mounted thereon, and an overcoat layer which is present in a tape carrier package after electronic parts are mounted. However, an object of the present invention is to improve tackiness which is particularly a problem in the past. When tackiness is mentioned, reference is made to the tackiness of an overcoat layer which is present in a flexible wiring board for a tape carrier package in a state that mainly electronic parts such as a semiconductor chip or the like are not mounted thereon.

The thickness of the overcoat layer is from about 0.5 to 200 μm, particularly from about 1 to 100 μm, and further from about 1 to 50 μm (the materials will be described later).

Furthermore, the encapsulating resin or underfill material is used for the purpose of protecting the semiconductor chip after the semiconductor chip is mounted. It is not particularly limited, but an epoxy-based resin composition is usually used.

The flexible wiring board for a tape carrier package of the present invention is provided with an overcoat layer containing at least a porous fine particle as a filler and a resin cured material. This porous fine particle functions to reduce tackiness on the surface of the overcoat layer. Moreover, while tackiness is reduced, general properties required as the overcoat layer is maintained or improved.

Porous particles are preferably present more in population on the surface rather than the central portion when the cross section in the thickness direction of the overcoat layer is viewed. Further, at the same time, porous particles are preferably present more on the outside surface than the interface side to the insulating film. Porous particles that are present more on the surface can be confirmed by the SEM picture, TEM picture of the cross section or the like. The reason why porous particles are more present on the surface is considered because, when an overcoat layer is formed by curing a curable resin composition containing porous fine particles, porous fine particles are easy to be distributed on the surface layer of the overcoat layer at a more high density, or easy to be positioned on the surface of the overcoat layer at a high density due to its porous structure. As a result, the proportion of the resin component exposed on the surface of the overcoat layer is lowered, whereby the tackiness of the surface is reduced, while general properties required as an overcoat layer are maintained or improved.

In the present invention, the porous fine particle is not particularly limited as long as it is a porous fine particle having pores. It is suitable that the porous fine particle has a number average particle diameter measured by a laser method of not more than 30 μm so that tackiness can be improved and other properties required for an overcoat layer can be good. When the particle diameter is great, porous fine particles come across between wiring patterns so that the insulation reliability is lowered. The average particle diameter of the porous fine particle is preferably from about 0.001 to about 30 μm, more preferably from about 0.005 to about 10 μm, and further preferably from about 0.005 to about 5 μm.

An average particle diameter of the porous particle is preferably smaller than the thickness of the overcoat layer, and more preferably smaller than ½ of the layer thickness.

Using non-porous fine particles, tackiness may be improved by using them in large quantities or using large particles. In this case, however, general properties required as an overcoat layer are deteriorated (for example, mechanical strength of the overcoat layer decreases, which may cause peeling at the time of bending or or cause whitening), and therefore the non-porous fine particles cannot be used.

As the porous fine particle, inert materials are practically suitable to the resin component contained in the resin composition for forming an overcoat layer. Examples of the material of porous fine particle include metal hydroxides such as silica, glass, alumina, zeolite, aluminum hydroxide and the like; silicates such as diatomaceous earth, calcium silicate and the like; phosphates such as calcium phosphate and the like; carbonates such as calcium carbonate and the like; magnesium silicates such as sepiolite and the like; activated carbons, acryl resins, polyimide resins, urethane resins, chitosan resins, polysiloxane resins, silicone rubbers, cellulose acetate resins and complexes thereof.

Furthermore, the shape of the porous fine particle is not limited. Examples thereof include sphere-shaped, scale-shaped, needle-shaped, amorphous powder-shaped, plate-shape, honeycomb-shaped porous fine particles and the like. In case of the sphere-shaped particle, fluidity of the resin composition can be suitably controlled; therefore, it is preferable. Furthermore, the porous fine particle can be suitably used with its hydrophilic surface as it is, but porous fine particle with its surface subjected to hydrophobic treatment by a silane coupling agent, a titanium coupling agent or the like can also be suitably used as long as porous property is maintained. Incidentally, in the present invention, when a chemical substance is filled or loaded in pores of the porous fine particle, the effect of reduction of tackiness is lowered, general properties required as an overcoat layer are worsened, or a chemical reaction with the resin component may take place; therefore, such porous fine particles are not suitably used.

In the present invention, when the porous fine particle has a specific surface area measured by the BET method of preferably about 200 to 1,000 m²/g, and more preferably about 250 to 1,000 m²/g, it is highly effective to reduce tackiness because the porous fine particle is distributed on the surface layer of the overcoat layer with higher density or easy to be positioned on the surface of the overcoat layer; therefore, such porous fine particles are suitable. Furthermore, when a pore volume of the porous fine particle is preferably from 0.1 ml/g to 10 ml/g, and more preferably from 0.3 to 3 ml/g converted at the oil absorption of the refined linseed oil method according to JIS K 5101-13-1, it is highly effective to reduce tackiness because the porous fine particle is distributed on the surface layer of the overcoat layer with higher density or easy to be positioned on the surface of the overcoat layer; therefore, such porous fine particles are suitable.

In the present invention, as the porous fine particle, porous silica is particularly suitable. Porous silica has a suitable specific surface area and a pore volume (oil absorption). In other words, since the apparent specific gravity is small, the porous fine particle is suitably distributed on the surface layer of the overcoat layer with higher density, or positioned on the surface of the overcoat layer with higher density. Furthermore, porous silica is stable in a curing process of the resin composition or in a mounting process of the tape carrier package, and no adverse effect is given to insulation performance or the like, and mechanical properties of the overcoat layer is not lowered either. Namely, the effect on the reduction of tackiness is great and properties as an overcoat layer are excellent; therefore, porous silica is particularly suitable.

The porous fine particle, particularly porous silica, is capable of reducing tackiness on the surface of a cured material (an overcoat layer) and enhancing surface hardness as compared to a case in which no porous fine particle is present. When surface hardness of the overcoat layer is enhanced, handling becomes easy as the same manner as reduced tackiness on the surface and anti-scratching property is also enhanced. So, it becomes possible to enhance the productivity in a process for the manufacture of a flexible wiring board for a tape carrier package and improve conveyance property in a mounting process of the flexible wiring board for a tape carrier package.

Incidentally, the porous fine particle is easy to be distributed on the surface layer of the overcoat layer with higher density or positioned on the surface of the overcoat layer with higher density because of its porous structure. As a result, the proportion of the resin component exposed on the surface of the overcoat layer is lowered, thus reducing tackiness and enhancing surface hardness. Deterioration of other general properties (the entire overcoat layer becomes rigid, thus lowering the flexibility required for an overcoat layer or the like) is suppressed.

Suitable examples of the porous silica include Sylysia, Sylophobic, Sylosphere (products of Fuji Silysia Chemical Ltd.), Tokusil, Finesil (products of Tokuyama Corp.), Sunsphere, M.S.GEL, Sunlovely (products of AGC Si-Tech Co., Ltd.), Mizukasil (a product of Mizusawa Industrial Chemicals, Ltd.) and the like. These product names are assumed trade marks.

In the present invention, the porous fine particle is contained in the curable resin composition, and used for the formation of an overcoat layer. The content of the porous fine particle in the curable resin composition is from 0.1 to 50 weight parts, preferably from 0.1 to 30 weight parts and more preferably from 0.2 to 30 weight parts, based on 100 weight parts of the resin solid component. When the porous fine particle is contained in excess of 50 weight parts, warpage becomes larger, mechanical strength specifically elongation becomes too small so that peeling or crack occurs or whitening occurs when the overcoat layer is bended; therefore, it is not preferable. Furthermore, when the content is less than 0.1 weight part, the effect of improving tackiness becomes small.

In the present invention, the curable resin composition for forming an overcoat layer is not particularly limited. In addition to the fact that the aforementioned porous fine particle is essentially contained, a curable resin composition which is usually used for overcoat (solder resist) can be suitably used. This curable resin composition may be thermosetting or photosetting, or it may be a resin composition with thermosetting and photosetting properties. Suitable examples of the thermosetting resin composition include a polyurethane resin composition, a polyamideimide resin composition, a polyimidesiloxane resin composition, a modified polyimide resin composition and the like as described in Patent Documents 1 to 5, the disclosures of which are incorporated herein as a part of this specification by reference. In these resin compositions, an epoxy resin or polyvalent isocyanate is suitably contained as a curing component for thermosetting. Into the photosetting resin composition is introduced a photosensitive group such as acrylate, methacrylate or the like as a resin component.

The curable resin composition for forming an overcoat layer of the present invention is used to form a coating film having a thin film thickness according to a method such as screen printing or the like and followed by curing, and is usually a solution composition.

In the present invention, suitably used is a solution composition having a concentration of the resin solid content of from about 20 to 80 weight %. Its solution viscosity is not particularly limited, but the solution viscosity at room temperature (25 degree centigrade) is from 5 to 1,000 Pa·s, particularly from 10 to 100 Pa·s and further from 10 to 60 Pa·s. Such a viscosity is suitable from the standpoints of workability of screen printing or solution properties, physical properties of a cured insulating film obtained, and the like.

Suitable examples of the solvent of the solution composition include nitrogen-containing solvents such as N,N-dimethylacetamide, N,N-diethylacetamide, N,N-dimethylformamide, N,N-diethylformamide, N-methyl-2-pyrrolidone, 1,3-dimethyl-2-imidazolidinone, N-methylcaprolactam and the like; sulfur-containing solvents such as dimethyl sulfoxide, diethyl sulfoxide, dimethyl sulfone, diethyl sulfone, hexamethylsulforamide and the like; and oxygen-containing solvents such as phenol type solvents (e.g. cresol, phenol, xylenol and the like), diglyme type solvents [e.g. diethylene glycol dimethyl ether (diglyme), triethylene glycol dimethyl ether (triglyme), tetraglyme and the like], ketone type solvents (e.g. acetone, acetophenone, propiophenone, cyclohexanone, isophorone and the like), ether type solvents (e.g. ethylene glycol, dioxane, tetrahydrofuran and the like) and lactone type solvents (e.g. γ-butyrolactone and the like). Particularly suitably used are N-methyl-2-pyrrolidone, N,N-dimethyl sulfoxide, N,N-dimethylformamide, N,N-diethylformamide, N,N-dimethylacetamide, N,N-diethylacetamide, γ-butyrolactone, triethylene glycol dimethyl ether and the like.

Furthermore, the curable resin composition may contain a non-porous filler (fine powder silica, talc, mica, barium sulfate and the like), a curing catalyst, a pigment (e.g. an organic coloring pigment, an inorganic coloring pigment and the like), a defoaming agent, a leveling agent, a rust prevention agent, an ion catcher or the like, as similar to the composition of the usual curable resin for overcoat.

The curable resin composition is coated on the pattern surface of an insulating film having a wiring pattern, by a method such as screen printing or the like, in such a thickness that the thickness of dried film becomes about 0.5 to 200 μm and particularly about 1 to 100 μm; thereafter, heat treatment is conducted at about 80 to 210 degree centigrade, preferably 100 to 200 degree centigrade for about 0.1 to 120 minutes, preferably about 1 to 60 minutes to perform curing, or a light is irradiated. If necessary heating is conducted to perform post-curing to perform curing; thereby, an overcoat layer is formed. Heating can be conducted by employing far infrared rays or the like as well as heating by a heater.

The overcoat layer fills each pattern space between wirings satisfactorily and has flexibility of an initial modulus at 25 degree centigrade of about 10 to 1,200 MPa and preferably about 10 to 1,000 MPa, electrical insulation of sufficient level (a volume insulation resistance of ordinarily not less than 10¹² Ω·cm, preferably not less than 10¹³ Ω·cm), and solder heat resistance of 10 seconds at 260 degree centigrade. Further preferably, the overcoat layer is small in warpage and superior in flatness and is excellent in bending resistance, adhesiveness to a substrate and an encapsulating agent (also including underfill), solvent resistance (solvent resistance to, for example, acetone, isopropanol and methyl ethyl ketone), metal plating resistance, resistance to penetration of tin into boundary, insulation reliability, and the like. In the flexible wiring board for a tape carrier package of the present invention, the overcoat layer has good general properties as described above and simultaneously has a reduced tackiness.

It is preferable that the flexible wiring board for a tape carrier package of the present invention is provided with an overcoat layer with tackiness such that the overcoat layer is not attached to SUS at 140 degree centigrade nor attached to polyimide at 60 degree centigrade. Such properties can be attained by properly selecting properties and amount of porous particle.

It is particularly preferable that the flexible wiring board for a tape carrier package of the present invention is provided with an overcoat layer which is composed of a polyurethane resin composition, particularly a polyurethane resin composition obtained by combining polybutadiene diol and/or polycarbonate diol and an isocyanate compound, a polyamideimide resin composition, a polyimidesiloxane resin composition, a polycarbonate-modified polyimide resin composition, or a butadiene-modified polyimide resin composition, and porous silica contained therein. As a result, its tackiness is improved and general properties required for an overcoat layer are good.

According to the present invention, it is possible to obtain a flexible wiring board for a tape carrier package with reduced tackiness, and a tape carrier package formed by using the flexible wiring board. As a result, it is possible to wind the flexible wiring board around a reel without through a peeling film. Furthermore, the tape carrier package which is mounted using the flexible wiring board for a tape carrier package of the present invention can be wound around a reel without through a peeling film either. Furthermore, in the flexible wiring board for a tape carrier package of the present invention, the productivity thereof can be improved. This is because, to form an overcoat layer, for coating and curing the curable resin composition, a simple curing process such as heating by an irradiation with far infrared rays or the like for a short period of time can be easily adopted. Further, since the flexible wiring board for a tape carrier package of the present invention is excellent in conveyance property in a mounting process for mounting a semiconductor chip, the productivity in the mounting process can be improved.

### EXAMPLES

The present invention is now illustrated in detail below with reference to Examples and Comparative Examples. However, the present invention is not restricted to the following Examples.

In the following respective Examples, measurement and evaluation were conducted in the following manner.

<Anti-Tackiness Property to SUS (Thermosetting)>

A composition for an overcoat layer was coated on a polyimide film (UPILEX 35SGA, a product of Ube Industries, Ltd.), and the resulting material was heated at 80 degree centigrade for 30 minutes and then heated at 120 degree centigrade for 90 minutes to form a film for evaluation having a thickness of about 10 μm. This film sample for evaluation was cut into a size of 2.5 cm in width and 5 cm in length to prepare a sample. This sample was put on a hot plate heated at 140 degree centigrade in such a way that the surface of the coating film faced upward, and a SUS weight (bottom area: 2 cm×5 cm, weight: 500 g) was placed thereon for 30 seconds and lifted. At that time, a case in which the weight was not attached was indicated with o (good), while a case in which it was attached was indicated with x (bad).

<Anti-Tackiness Property to Polyimide (Thermosetting)>

A composition for an overcoat layer was coated on a polyimide film (UPILEX 35SGA, a product of Ube Industries, Ltd.), and the resulting material was heated at 80 degree centigrade for 30 minutes and then heated at 120 degree centigrade for 90 minutes to form a film for evaluation having a thickness of about 10 μm. This film sample for evaluation was cut into a size of 2.5 cm in width and 5 cm in length to prepare a sample. This sample was put on a hot plate heated at 60 degree centigrade in such a way that the surface of the coating film faced upward, and a polyimide film (UPILEX 35SGA, area: 1 cm×5 cm, a product of Ube Industries, Ltd.) was laminated thereon and further a load of 1 kg weight was applied for 30 seconds. Thereafter, a case in which the weight was not attached to the polyimide film was indicated with o (good), while a case in which it was attached thereto was indicated with x (bad).

<Anti-Tackiness Property to SUS (Far Infrared Ray Curing)>

A composition for an overcoat layer was coated on a polyimide film (UPILEX 35SGA, a product of Ube Industries, Ltd.), and the resulting material was heated at 160 degree centigrade for 10 minutes using a far infrared curing machine to form a film for evaluation having a thickness of about 10 μm. This film sample for evaluation was cut into a size of 2.5 cm in width and 5 cm in length to prepare a sample. This sample was put on a hot plate heated at 140 degree centigrade in such a way that the surface of the coating film faced upward, and a SUS weight (bottom area: 2 cm×5 cm, weight: 500 g) was placed thereon for 30 seconds and lifted. At that time, a case in which the weight was not attached was indicated with o (good), while a case in which it was attached was indicated with x (bad).

<Anti-Tackiness Property to Polyimide (Far Infrared Ray Curing)>

A composition for an overcoat layer was coated on a polyimide film (UPILEX 35SGA, a product of Ube Industries, Ltd.), and the resulting material was heated at 160 degree centigrade for 10 minutes using a far infrared curing machine to form a film for evaluation having a thickness of about 10 μm. This film sample for evaluation was cut into a size of 2.5 cm in width and 5 cm in length to prepare a sample. This sample was put on a hot plate heated at 60 degree centigrade in such a way that the surface of the coating film faced upward, and a polyimide film (UPILEX 35SGA, area: 1 cm×5 cm, a product of Ube Industries, Ltd.) was laminated thereon and further a load of 1 kg weight was applied for 30 seconds. Thereafter, a case in which the weight was not attached to the polyimide film was indicated with o (good), while a case in which it was attached thereto was indicated with x (bad).

<Surface Hardness>

A composition for an overcoat layer was coated on the luster surface of a 35 μm-thick electrolytic copper foil, and the resulting material was heated at 80 degree centigrade for 30 minutes and then heated at 120 degree centigrade for 90 minutes to form a film for evaluation having a thickness of about 100 μm. This film for evaluation was evaluated by JIS K 5600-5-4 scratch hardness (pencil method).

<Initial Modulus>

A sheet-shaped sample was formed by heating test composition at 80 degree centigrade for 30 minutes and then heating at 120 degree centigrade for 90 minutes and performing curing so as to have a thickness of about 100 μm. The sheet-shaped sample was cut into a size of 1 cm in width and 7 cm in length for use in the test. The sample was measured at a temperature of 25 degree centigrade, a humidity of 50% RH, a cross-head rate of 50 mm/min., and a distance between chucks of 5 cm.

<Solder Heat Resistance>

A composition for an overcoat layer was coated on the luster surface of a 35 μm-thick electrolytic copper foil, and the resulting material was heated at 80 degree centigrade for 30 minutes and then heated at 120 degree centigrade for 90 minutes to form a film for evaluation having a thickness of about 10 μm. On the film for evaluation was coated a rosin-based flux (SUNFLUX SF-270, a product of Sanwa Chemical Industrial Co., Ltd.), and then the film sample was contacted with a solder bath of 260 degree centigrade for 10 seconds. Then, the appearance of the sample was observed for evaluation. A case in which there was no abnormal change was indicated with o, while a case in which there was blistering and/or melting was indicated with x.

<Warpage>

A composition for an overcoat layer was coated on a polyimide film (UPILEX 35SGA, a product of Ube Industries, Ltd.), and the resulting material was heated at 80 degree centigrade for 30 minutes and then heated at 120 degree centigrade for 90 minutes to form a film for evaluation having a thickness of about 10 μm. This film for curing evaluation on the polyimide was cut into a size of 5 cm×5 cm. A case in which the average height of the four edges was less than 1 mm was indicated with o (good), while it was not less than 1 mm was indicated with x (bad).

The compounds, epoxy resins, curing catalysts, fillers and porous fine particles used in the following respective Examples will be explained.

<Tetracarboxylic Acid>

2,3,3′,4′-biphenyltetracarboxylic acid dianhydride (a product of Ube Industries, Ltd.)

<Diamine Compound>

isophorone diamine (a product of Wako Pure Chemical Industries, Ltd.)

α,ω-bis(3-aminopropyl)polydimethylsiloxane (amino equivalent: 460) (a product of Shin-Etsu Chemical Co., Ltd.)

bis(3-carboxy-4-aminophenyl)methane-(4,4′-diamino-3,3′-dicarboxyphenylmethane) (a product of Wakayama Seika Kogyo Co., Ltd.)

<Monoamine having One Alcoholic Hydroxyl Group>

3-aminopropanol (a product of Wako Pure Chemical Industries, Ltd.)

<Diol Containing Reactive Polar Group>

2,2-bis(hydroxymethyl)propionic acid (a product of KOEI PERSTORP Co., Ltd.)

<Polycarbonate Diol>

Kuraray Polyol C-2015 (a product of Kuraray Co., Ltd., average molecular weight: 2000)

<Diisocyanate Compound>

4,4′-diphenylmethane diisocyanate (a product of Nippon Polyurethane Industry Co., Ltd.)

<Organic Solvent>

γ-butyrolactone (a product of Wako Pure Chemical Industries, Ltd.)

<Epoxy Resin>

Epolead 2021P (a product of Daicel Chemical Industries, Ltd.)

Epikote 828EL (a product of Japan Epoxy Resins Co., Ltd., epoxy equivalent: 184 to 194)

<Blocked Isocyanate>

Takenate B830 (a product of Mitsui Takeda Chemicals, Inc, NCO (wt %): 7.0)

Duranate ME20-B80S (a product of Asahi Kasei Chemicals Corp., NCO (wt %): 5.8)

<Curing Catalyst>

DBU (a product of Aldrich Corp., 1,8-diazabicyclo[5,4,0]-7-undecene)

Curezol 2E4MZ (a product of Shikoku Chemicals Corp., 2-ethyl-4-methylimidazole)

<Filler>

Aerosil 130 (a product of Nippon Aerosil Co., Ltd., specific surface area (BET method): 130 m²/g)

Aerosil R972 (a product of Nippon Aerosil Co., Ltd., specific surface area (BET method): 110 m²/g)

<Phenolic Resin>

phenol formaldehyde resin H-1 (a product of Meiwa Plastic Industries, Ltd.)

<Porous Fine Particle>

Sylophobic 100 (hydrophobic silica gel, a product of Fuji Silysia Chemical Ltd., average particle diameter (laser method): 2.7 μm, specific surface area (BET method): 300 m²/g, oil absorption: 240 ml/100 g)

Sylysia 310P (hydrophilic silica gel, a product of Fuji Silysia Chemical Ltd., average particle diameter (laser method): 2.7 μm, specific surface area (BET method): 300 m²/g, oil absorption: 310 ml/100 g)

Sylysia 710 (hydrophilic silica gel, a product of Fuji Silysia Chemical Ltd., average particle diameter (laser method): 2.8 μm, specific surface area (BET method): 700 m²/g, oil absorption: 100 ml/100 g)

### Reference Example 1

<Production of an Imide Oligomer Solution Having an Alcoholic Hydroxyl Group at the Terminal>

Into a 5-liter glass separable flask equipped with a nitrogen inlet tube, a Dean-Stark receiver and a condenser tube were fed 1,471 g (5 mol) of 2,3,3′,4′-biphenyltetracarboxylic dianhydride, 507 g (11 mol) of ethanol and 2,092 g of γ-butyrolactone, and the resulting mixture was stirred in a nitrogen atmosphere at 90 degree centigrade for 1 hour. Then, 376 g (5 mol) of 3-aminopropanol and 426 g (2.5 mol) of isophorone diamine were fed thereinto. The solution was heated in a nitrogen atmosphere at 120 degree centigrade for 2 hours and at 180 degree centigrade for 2 hours, water generated by the imidization reaction was removed by blowing nitrogen into the reaction solution. This imide oligomer solution having an alcoholic hydroxyl group at the terminal had the solid content of 50.3%.

### Reference Example 2

<Production of a Polycarbonate-Modified Polyimide Resin Solution>

Into a 5-liter glass flask equipped with a nitrogen inlet tube were fed 600 g (0.3 mol) of Kuraray Polyol C-2015N, 188 g (0.75 mol) of 4,4′-diphenylmethane diisocyanate and 535 g of γ-butyrolactone, and the resulting mixture was stirred in a nitrogen atmosphere at 60 degree centigrade for 3 hours. Then, 40.2 g (0.3 mol) of 2,2-bis(4-hydroxymethyl)propionic acid, 499 g (0.3 mol) of the imide oligomer solution having an alcoholic hydroxyl group at the terminal synthesized in Reference Example 1 and 100 g of γ-butyrolactone were added thereto, and the resulting mixture was stirred at 80 degree centigrade for 10 hours. The obtained modified polyimide resin solution was a solution having a concentration of a polymer solid content of 50% and a viscosity of 256 Pa·s (logarithmic viscosity ηᵢₙₕ of 0.230).

### Reference Example 3

<Production of a Polyimide Polysiloxane Resin Solution>

Into a 500-ml glass flask were fed 47.1 g (0.16 mol) of 2,3,3′,4′-biphenyltetracarboxylic acid dianhydride and 100 g of triglyme (a solution) (hereinafter to be abbreviated as TG), and the resulting mixture was heated and stirred in a nitrogen atmosphere at 80 degree centigrade. 125.1 g (0.136 mol) of α,ω-bis(3-aminopropyl)polydimethylsiloxane (amino equivalent: 460) and 40 g of TG were added thereto, and the resulting mixture was heated and stirred at 180 degree centigrade for 60 minutes. Furthermore, to this reaction solution were added 6.9 g (0.024 mol) of bis(3-carboxy-4-aminophenyl)methane-(4,4′-diamino-3,3′-dicarboxyphenylmethane) and 39 g of TG, and the mixture was heated and stirred at 180 degree centigrade for 15 hours. Then, filtration was conducted. The polyimidesiloxane reaction solution obtained was a solution having a concentration of a polymer solid content of 50 weight %, and ηᵢₙₕ of 0.200. The rate of imidization was substantially 100%.

### Example 1

In a glass vessel, to the polycarbonate-modified polyimide resin solution obtained in Reference Example 2 were added 10 weight parts of epoxy resin (Epolead 2021P), 20 weight parts of blocked isocyanate (Takenate B830), 30 weight parts of blocked isocyanate (Duranate ME20-B80S), 2.5 parts of a phenolic resin H-1, 0.5 weight part of a curing catalyst DBU, 0.5 part of Curezol 2E4MZ, a defoaming agent OX-881 and 60 weight parts of γ-butyrolactone, based on 100 weight parts of a polycarbonate-modified polyimide resin, and the resulting mixture was uniformly stirred and mixed. Furthermore, 7 weight parts of Aerosil R972 as a filler and 2 weight parts of porous silica Sylophobic as a porous fine particle were added, and the resulting mixture was mixed, and then kneaded by using 3 rolls to obtain a polycarbonate-modified polyimide resin composition. A film for evaluation of a prescribed thickness was formed by thermosetting or far infrared ray curing of this composition, and tackiness of the SUS surface and polyimide, surface hardness, initial modulus, solder heat resistance and warpage were evaluated.

### Examples 2 to 6

A composition for an overcoat layer was obtained in the same manner as in Example 1, except that porous silica as shown in Table 1 was added as a porous fine particle. These compositions for an overcoat layer were evaluated in the same manner as in Example 1. The results are shown in Table 1.

### Example 7

In a glass vessel, to the polyimidesiloxane resin solution obtained in Reference Example 3 were added 18 weight parts of an epoxy resin (Epikote 828EL), 0.2 weight part of a curing catalyst 2E4MZ and 6 weight parts of a defoaming agent DB-100, based on 100 weight parts of the polyimidesiloxane resin, and the resulting mixture was uniformly stirred and mixed. Furthermore, 23 weight parts of Aerosil 130 as a filter and 10 weight parts of porous silica (Sylysia 310P) as a porous fine particle were added, and the resulting mixture was stirred, and then kneaded by using 3 rolls to obtain a composition for an overcoat layer. This composition for an overcoat layer was evaluated in the same manner as in Example 1. The results are shown in Table 1.

### Comparative Example 1

A polycarbonate-modified polyimide composition was formulated in the same manner as in Example 1 without adding porous silica. This composition for an overcoat layer was evaluated in the same manner as in Example 1. The results are shown in Table 1. A film obtained by thermosetting or far infrared ray curing of this composition could not satisfy anti-tackiness property to the SUS surface and polyimide surface.

### Comparative Example 2

A polyimidesiloxane resin composition was formulated in the same manner as in Example 3 without adding porous silica. This composition for an overcoat layer was evaluated in the same manner as in Example 1. The results are shown in Table 1. A film for evaluation obtained by thermosetting or far infrared ray curing of this composition could not satisfy anti-tackiness property to the SUS surface and polyimide surface.

### Comparative Example 3

A composition for an overcoat layer was obtained in the same manner as in Example 1, except that porous silica as shown in Table 1 was added as a porous fine particle. This composition for an overcoat layer was evaluated in the same manner as in Example 1. The results are shown in Table 1. This composition could not satisfy low warpage property required for an overcoat layer of a wiring board for a tape carrier package.

TABLE 1

| | | Example 1 | Example 2 | Example 3 | Example 4 |
|---|---|---|---|---|---|
| Polymer | | Reference | Reference | Reference | Reference |
| | | Example 2 | Example 2 | Example 2 | Example 2 |
| Porous | (weight parts) | 100 | 100 | 100 | 100 |
| particle | Sylophobic | 2 | 10 | 20 | — |
| | 100 (weight | | | | |
| | parts) | | | | |
| | Sylysia 310P | — | — | — | 5 |
| | (weight parts) | | | | |
| | Sylysia 710 | — | — | — | — |
| | (weight parts) | | | | |

Evaluation Results

| | | | | |
|---|---|---|---|---|
| Anti-tackiness property | ◯ | ◯ | ◯ | ◯ |
| With SUS surface | | | | |
| (thermosetting) | | | | |
| Anti-tackiness property | ◯ | ◯ | ◯ | ◯ |
| With polyimide | | | | |
| (thermosetting) | | | | |
| Anti-tackiness property | ◯ | ◯ | ◯ | ◯ |
| With SUS surface | | | | |
| (far infrared ray curing) | | | | |
| Anti-tackiness property | ◯ | ◯ | ◯ | ◯ |
| With polyimide | | | | |
| (far infrared ray curing) | | | | |
| Surface hardness | H | 2H | 2H | 2H |
| Initial modulus (MPa) | 310 | 320 | 450 | 290 |
| Solder heat resistance | ◯ | ◯ | ◯ | ◯ |
| Warpage | ◯ | ◯ | ◯ | ◯ |

| | | Example 5 | Example 6 | Example 7 |
|---|---|---|---|---|
| Polymer | | Reference | Reference | Reference |
| | | Example 2 | Example 2 | Example 3 |
| Porous | (weight parts) | 100 | 100 | 100 |
| particle | Sylophobic 100 | — | — | — |
| | (weight parts) | | | |
| | Sylysia 310P | 10 | — | 10 |
| | (weight parts) | | | |
| | Sylysia 710 | — | 20 | — |
| | (weight parts) | | | |

Evaluation Results

| | | | |
|---|---|---|---|
| Anti-tackiness property | ◯ | ◯ | ◯ |
| With SUS surface | | | |
| (thermosetting) | | | |
| Anti-tackiness property | ◯ | ◯ | ◯ |
| With polyimide | | | |
| (thermosetting) | | | |
| Anti-tackiness property | ◯ | ◯ | ◯ |
| With SUS surface | | | |
| (far infrared ray curing) | | | |
| Anti-tackiness property | ◯ | ◯ | ◯ |
| With polyimide | | | |
| (far infrared ray curing) | | | |
| Surface hardness | 2H | 2H | 2B |
| Initial modulus (MPa) | 320 | 950 | 470 |
| Solder heat resistance | ◯ | ◯ | ◯ |
| Warpage | ◯ | ◯ | ◯ |

| | | Comparative | Comparative | Comparative |
|---|---|---|---|---|
| | | Example 1 | Example 2 | Example 3 |
| Polymer | | Reference | Reference | Reference |
| | | Example 2 | Example 3 | Example 2 |
| Porous | (weight parts) | 100 | 100 | 100 |
| particle | Sylophobic 100 | — | — | 70 |
| | (weight parts) | | | |
| | Sylysia 310P | — | — | — |
| | (weight parts) | | | |
| | Sylysia 710 | — | — | — |
| | (weight parts) | | | |

Evaluation Results

| | | | |
|---|---|---|---|
| Anti-tackiness property | X | X | ◯ |
| With SUS surface | | | |
| (thermosetting) | | | |
| Anti-tackiness property | X | X | ◯ |
| With polyimide | | | |
| (thermosetting) | | | |
| Anti-tackiness property | X | X | ◯ |
| With SUS surface | | | |
| (far infrared ray curing) | | | |
| Anti-tackiness property | X | X | ◯ |
| With polyimide | | | |
| (far infrared ray curing) | | | |
| Surface hardness | H | 2B | — |
| Initial modulus (MPa) | 210 | 400 | — |
| Solder heat resistance | ◯ | ◯ | ◯ |
| Warpage | ◯ | ◯ | X |

### INDUSTRIAL APPLICABILITY

According to the present invention, it is possible to provide a flexible wiring board for a tape carrier package with reduced tackiness and a tape carrier package formed by using the flexible wiring board. As a result, it is possible to eliminate a peeling film when the flexible wiring board for a tape carrier package is wound around a reel, improve the productivity in a process for the manufacture of the flexible wiring board for a tape carrier package, enhance conveyance property in a mounting process of the flexible wiring board for a tape carrier package, and the like.

1. A flexible wiring board for a tape carrier package comprising:
an insulating film,
a wiring pattern formed on a surface of the insulating film, and
an overcoat layer containing a resin cured material and a porous fine particle, and protecting at least a region of said wiring pattern.

2. The flexible wiring board for a tape carrier package according to claim 1, wherein tackiness of said overcoat layer satisfies the conditions such that said overcoat layer is not attached to SUS at 140 degree centigrade and is not attached to polyimide at 60 degree centigrade.

3. The flexible wiring board for a tape carrier package according to claim 1, wherein said porous fine particle is contained in the ratio of 0.1 to 50 weight parts, based on 100 weight parts of said resin cured material.

4. The flexible wiring board for a tape carrier package according to claim 1, wherein an average particle diameter of said porous fine particle is smaller than the thickness of said overcoat layer, and
said porous fine particles are present more in population on the surface than in the central portion in the thickness direction of the overcoat layer.

5. The flexible wiring board for a tape carrier package according to claim 1, wherein an average particle diameter of said porous fine particle is not more than 30 μm and a specific surface area thereof is not less than 200 m²/g.

6. The flexible wiring board for a tape carrier package according to claim 1, wherein a pore volume of said porous fine particle is not less than 0.1 ml/g converted at the oil absorption of the refined linseed oil method according to JIS K 5101-13-1.

7. The flexible wiring board for a tape carrier package according to claim 1, wherein said porous fine particle is porous silica.

8. The flexible wiring board for a tape carrier package according to claim 1, wherein said resin cured material contains a cured material of at least one resin selected from the group consisting of a polyurethane resin, a polyamideimide resin, a polyimidesiloxane resin and a modified polyimide resin.

9. The flexible wiring board for a tape carrier package according to claim 1, wherein said resin cured material is heated by far infrared rays and cured.

10. The flexible wiring board for a tape carrier package according to claim 1, wherein it is wound round a reel without through a peeling film.

11. A tape carrier package formed by using the flexible wiring board for a tape carrier package according to claim 1.

12. A curable resin composition for overcoat, wherein a porous fine particle and a curable resin are contained, and when cured, tackiness on the surface of the resin cured material is reduced as compared to a case in which no porous fine particle is present.

13. The curable resin composition for overcoat according to claim 12, wherein the tackiness satisfies the conditions such that the resin cured material is not attached to SUS at 140 degree centigrade and is not attached to polyimide at 60 degree centigrade after curing.

14. The curable resin composition for overcoat according to claim 12, wherein said curable resin contains at least one resin selected from the group consisting of a polyurethane resin, a polyamideimide resin, a polyimidesiloxane resin and a modified polyimide resin.
